(19) United States
(12) Patent Application Publication
(10) Pub. No.: US 2025/0372410 A1
(43) Pub. Date: Dec. 4, 2025

(54) SYSTEM AND METHOD FOR MONITORING SUPERCRITICAL CO2 DRYING

(71) Applicant: KLA Corporation, Milpitas, CA (US)

(72) Inventors: Eugene Shalyt, Washington Township, NJ (US); Michael MacEwan, Tuxedo Park, NY (US); Yidan Bi, Bloomfield, NJ (US); Jake Zhu, Fair Lawn, NJ (US); Gary Tsai, Weehawken, NJ (US)

(73) Assignee: KLA Corporation, Milpitas, CA (US)

(21) Appl. No.: 19/201,612

(22) Filed: May 7, 2025

Related U.S. Application Data
(60) Provisional application No. 63/654,109, filed on May 31, 2024.

(51) Int. Cl. H01L 21/67; H01L 21/02; H01L 21/66

(52) U.S. Cl. CPC H01L 21/67034; H01L 21/02101; H01L 21/67253; H01L 21/67288; H01L 22/26

(57) ABSTRACT

The disclosed subject matter includes systems for monitoring of supercritical CO₂ drying by examining the exhaust, and methods thereof. The system includes a first pump to deliver liquid CO₂ and a second pump for a thermal moderator. Downstream, a heater generates a supercritical gas, with a detector including a sensor and a back-pressure valve maintaining its pressure. The sensor monitors the exhausted gas temperature to ensure a drying endpoint.

### CROSS-REFERENCE TO RELATED APPLICATIONS

This Non-Provisional Application claims priority from U.S. provisional application U.S. 63/654,109, filed on May 31, 2024, hereby incorporated by reference in its entirety.

### BACKGROUND

The disclosed subject matter relates generally to chemically analytical processes, and more particularly, to systems and methods for monitoring supercritical CO₂ drying.

Certain wet processing techniques for semiconductor devices require the application of potent chemicals for cleaning, followed by a critical drying phase. However, as device patterns become smaller and more intricate, the capillary forces from liquid drying methods can risk pattern collapse, a situation where high aspect-ratio patterns stick or deform due to surface tension. To mitigate this, low-surface-tension solvents have been employed.

Supercritical drying has emerged as a method for preventing pattern collapse, as it can eliminate surface tension during the drying process. The use of supercritical carbon dioxide (SC—CO₂) at high pressures further enables an extraction and displacement of contaminants from a substrate. Under these conditions, SC—CO₂ can enter the spaces among patterns and displace the contaminants without the influence of surface tension, and thus prevent collapse.

However, supercritical drying can introduce certain challenges, particularly in endpoint detection. Certain techniques for monitoring the supercritical drying process within the high-pressure chamber, e.g., gas chromatography (GC), can be time-consuming and require expensive reagents. GC can also be unsuitable for direct application in supercritical environments due to the high pressure and temperature involved, as well as low exhaust temperatures that can affect detection accuracy. Furthermore, the use of inline monitoring can disrupt the drying process, making it impractical for continuous, real-time detection.

Therefore, there is a need for an efficient technique to continuously monitor supercritical CO₂ drying.

### SUMMARY

The disclosed subject matter provides techniques that continuously monitor supercritical CO₂ drying with an accurate endpoint determination. The disclosed techniques provide for monitoring components of an exhaust gas downstream of drying, thus securing a non-intrusive, efficient, and low-cost detection for a drying endpoint without the drawbacks associated with certain traditional detection methods.

In one aspect, the disclosed subject matter provides systems for monitoring supercritical CO₂ drying. An example system includes a first pump configured to pump a first flow of liquid CO₂, a second pump configured to pump a second flow comprising isopropyl alcohol (IPA) that can be served as a solvent for CO₂, a heater provided downstream of the first pump and second pump and configured to generate a drying gas of supercritical CO₂, and a detector configured to detect an endpoint for drying a substrate therein. The detector is configured to detect an endpoint for the drying including a sensor positioned to continuously monitor an exhaust gas downstream of the drying and determine a concentration of IPA therein, and the endpoint is dependent on the determined IPA concentration.

In certain embodiments, the detector further comprises a back-pressure valve downstream of the sensor. The exhaust pipe is positioned downstream of the back-pressure valve. The threshold corresponds to a substantial absence of IPA. In certain embodiments, the detector further comprises an electronic module electrically connected with the sensor, and the electronic module is configured to determine whether to continue or terminate the drying.

The disclosed subject matter also provides methods for monitoring supercritical CO₂ drying. An example method comprises pumping a first flow of liquid CO₂ and a second flow of at least a thermal moderator comprising isopropyl alcohol (IPA) and/or H2O, mixing the first flow and second flow, generating a drying gas including supercritical CO₂ via heating, delivering the drying gas to a detector having a substrate, drying the substrate using the drying gas, and concurrently continuously monitoring IPA concentration in an exhaust gas downstream of the drying. The continuously monitoring comprises determining a concentration of IPA in the exhaust gas and an endpoint of the drying, wherein the endpoint is dependent on the determined IPA concentration.

In certain embodiments, the heating temperature is from 40-100° C. The exhaust gas can undergo an expansion with a pressure drop from 200 bar to 1 bar. In certain embodiments, the method further comprises releasing exhaust gas from the detector. In certain embodiments, the method further comprises regulating the pressure of the drying gas downstream of the drying.

In certain embodiments, the drying gas comprises IPA in an amount less than 10%. In certain embodiments, the endpoint is determined upon a substantial absence of IPA. In certain embodiments, the method further comprises monitoring IPA purity for identifying defects of the substrate. In certain embodiments, the defects comprise particles and moisture. In certain embodiments, the IPA purity is monitored by spectroscopic detection, gas chromatography, or electrical sensing.

### BRIEF DESCRIPTION OF THE DRAWINGS

Reference will now be made in detail to the various exemplary embodiments of the disclosed subject matter, which are illustrated in the accompanying drawings. The accompanying drawings, where like reference numerals refer to identical or functionally similar elements throughout the separate views, serve to further illustrate various embodiments and to explain various principles and advantages all in accordance with the disclosed subject matter. Color drawings have been submitted hereby, and it is believed that the disclosed subject matter is more clearly and fully described by full-color renderings of these figures.

FIG. 1 provides a schematic diagram of an exemplary system for monitoring supercritical CO₂ drying in an embodiment of the disclosed subject matter.

FIG. 2 provides a graph showing enthalpy dependence on temperature of CO₂ for isobars 10-1000 bar in an embodiment of the disclosed subject matter.

FIG. 3A provides a graph showing calibration curves for IPA content in supercritical CO₂ in an embodiment of the disclosed subject matter; FIG. 3B provides a graph showing the endpoint detection for supercritical CO₂ drying in an embodiment of the disclosed subject matter.

FIG. 4 provides a graph showing phase transitions between various phase for CO₂ at different temperature and pressure in an embodiment of the disclosed subject matter.

FIG. 5A provides a graph showing calibration for different IPA concentration on determining the drying endpoint in an embodiment of the disclosed subject matter; FIG. 5B provides a graph showing the endpoint determination indicating IPA concentration over time in an embodiment of the disclosed subject matter.

FIG. 6 provides a graph showing the final temperature of CO₂-IPA mixture depending on the fraction of IPA at 10% in an embodiment of the disclosed subject matter.

FIG. 7A provides a graph showing correlation of Acetone contaminant to liquid particle count (LPC) in an embodiment of the disclosed subject matter; FIG. 7B provides a graph showing comparison for monitoring moisture content in IPA between a non-reagent detection and a traditional Karl Fisher titration in an embodiment of the disclosed subject matter.

It is to be understood that both the foregoing general description and the following detailed description are exemplary and are intended to provide further explanation of the disclosed subject matter.

### DETAILED DESCRIPTION

The disclosed subject matter provides techniques of determining the endpoint of supercritical CO₂ drying of a semiconductor substrate via monitoring exhaust gas temperatures.

The terms used in this specification generally have their ordinary meanings in the art, within the context of the disclosed subject matter and in the specific context where each term is used. Certain terms are discussed below, or elsewhere in the specification, to provide additional guidance to the practitioner in describing the compositions and methods of the disclosed subject matter and how to make and use them. For purposes of interpreting this specification, the following definitions will apply and whenever appropriate, terms used in the singular will also include the plural and vice versa.

For example, the term “surface tension” refers to a type of force at an interface between liquid and another phase. It can be measured in milli Newtons per meter (mN/m). Certain mediums in the disclosed subject matter have surface tension as follows: Deionized Water (DIW) 72 mN/m, IPA at 20° C. 22 mN/m, IPA at 80° C. 17 mN/m, supercritical CO₂ 0 mN/m. Notably, Supercritical CO₂ has no surface tension as there is no substantial interface between distinct liquid and gas phases.

The term “back-pressure valve” refers to a type of pressure-regulating valve designed to maintain a set pressure within a system by controlling the flow of fluids or gases. The back-pressure valve ensures that the pressure upstream of the valve stays above a pre-defined threshold by releasing excess pressure, allowing the system to function within safe and efficient parameters and preventing pressure fluctuations during the flowing within the pipe or tube of the system.

The term “endpoint” herein refers to the moment when the drying process is complete, characterized with that the target materials being dried at this moment, e.g., a substrate, has reached to a threshold, corresponding to the desired level of liquid contaminants removal.

The term “drying gas” herein refers to a type of gas used to dry an object, e.g., a substrate, which can be formed by a mixing, and/or reacting. The term “exhaust gas” herein refers to a type of gas used to release outwardly from the monitor system, which typically discharges to waste unit or releases to the atmosphere. In the disclosed subject matter, the dry gas can be generated by mixing the two flows including liquid CO₂ and IPA under specific conditions, e.g., heating, and the exhaust gas is a downstream gas resulting from the drying process.

The disclosed subject matter introduces a monitoring approach for supercritical CO₂ with the endpoint detection by monitoring components in the exhaust gas mainly including CO₂. Such a monitoring approach can be a more efficient and cost-effective solution by focusing on changes in the exhaust gas rather than within the high-pressure cleaning chamber, avoiding complexities and high cost. Certain advantages of exhaust-based endpoint detection in the disclosed subject matter can include, but are not limited to, the following: a) real-time feedback: monitoring the exhaust allows for continuous, real-time analysis without disturbing the supercritical environment, giving immediate information on whether contaminants are still being displaced; b) lower equipment strain: exhaust gas monitoring operates at lower pressures and temperatures, making it compatible with simpler, less costly detection equipment, and reducing both initial capital expenditures and maintenance costs.

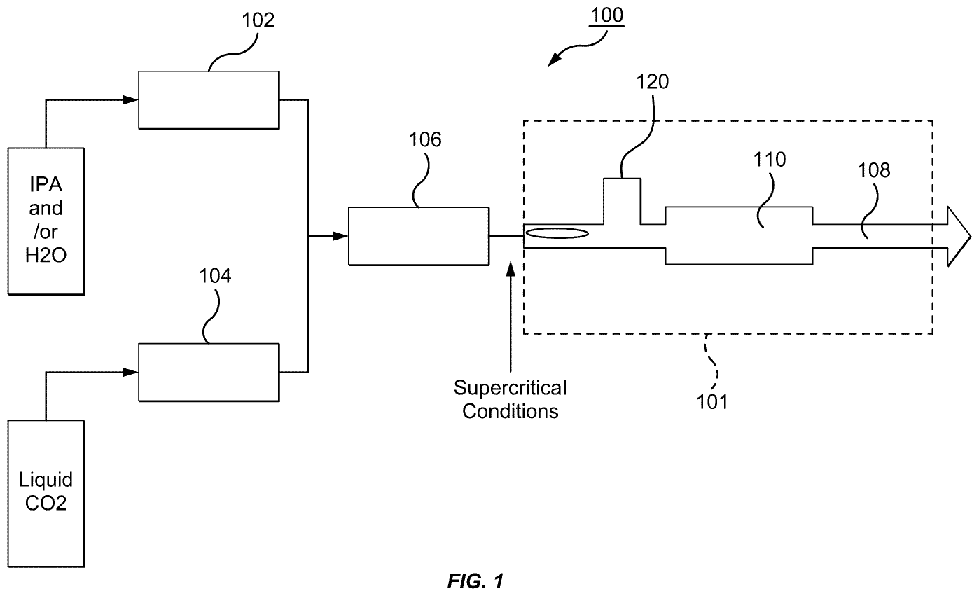

An exemplary system for monitoring supercritical CO₂ drying is illustrated with reference to FIG. 1. The system 100 is interconnected via a polarity of pipes connecting the various units. For example, a first pump 102 and a second pump 104 are fed with a first flow of liquid CO₂ and a second flow of at least a thermal moderator, respectively. The first pump 102 and the second pump 104 can be mounted on the pipes for delivering their liquid flows therewithin under high pressure into a heater 106 positioned downstream of both pumps 102 and 104, where the two flows are combined. The heater 106 can adjust the temperature of the combined flow to generate a drying gas comprising supercritical CO₂.

In certain embodiments, when the liquid CO₂ and thermal moderators are delivered into the heater 106, these flows are mixed and heated via the heater 106. This can maintain the temperature of the CO₂ above its critical temperature under a specific pressure to facilitate the transition to a supercritical state. Upon exiting the heater 106, the mixture of the two flows has transitioned into a drying gas comprising supercritical CO₂. Such a drying gas exhibits unique properties, e.g., having liquid and gas phases concurrently, enabling it to act as an efficient tool for various applications including extraction, drying, and cleaning for a semiconductor substrate. Notably, the generated drying gas serves as a drying gas applied to a substrate downstream.

Following the heater 106, a detector 101, including a sensor 120, a substrate subjected to be dried (not shown), and a back-pressure valve 110 therein, is equipped on a pipe, e.g., downstream of the heater 106, to maintain optimal drying conditions and/or monitoring performance for the drying gas exiting from the heater 106.

Within the detector 101, the drying process to the substrate is operated continuously. Following the drying, an exhaust gas is discharged and delivered into the sensor 120. The sensor 120 can continuously monitor the exhaust gas, focusing on the contaminants therein. Examples of suitable sensors in the disclosed subject matter include a residual gas analyzer (RGA), an infrared (IR) sensor, mass spectrometer, and a photoionization detector (PID). These sensors enable precise monitoring of contaminant levels during the drying process. In this example, the sensor 120 is strategically coupled to the exhaust pipe 108 to continuously monitor the components of the exhaust gas. The sensor 120 plays an important role in providing real-time feedback on the drying process, ensuring that contaminants in the exhaust gas reach at the desired value, e.g., a substantial absence of contaminants. By detecting and identifying the contaminants, the sensor 120 ensures determining the endpoint of the drying process and maintaining improved system performance upon the substantial absence of contaminants. In certain embodiments, the sensor 120 can be installed within the exhaust pipe 108.

A back-pressure valve 110 can be positioned downstream of the sensor 120. There may be a set pressure to maintain for the exhaust gas, more preferably at 80 bar, 100 bar, 150 bar, or 200 bar, corresponding to various temperatures. In this example, the back-pressure valve 110 can regulate the flow of the exhaust gas, preventing any significant pressure drops that could lead to phase changes or inefficiencies in the system. By preventing a pressure of the exhaust gas from an irregular fluctuation before releasing to the atmosphere, the back-pressure valve 110 helps to stabilize the properties of the exhaust gas.

In certain embodiments, the detector 101 further comprises an electronic module (not shown) electrically connected with the sensor 120. The electronic module can receive and analyze real-time signals from the sensor 120, compare the monitored IPA concentration to a predetermined threshold corresponding to a substantial absence of IPA, and determine whether to continue or terminate the drying process based on the comparison. The threshold corresponds to a substantial absence of IPA and can be set, for example, as less than 1 wt % of IPA in the exhaust gas.

Align with the system 100, an exemplary method for monitoring supercritical CO₂ drying is described in accordance with the disclosed subject matter. In certain embodiments, the method includes the following procedures. First, a first flow of liquid CO₂ is pumped along with a second flow of a thermal moderator. These flows are then combined, and a drying gas including supercritical CO₂ is generated through a heat exchange process. Following the generation of supercritical CO₂ as the drying gas, the method maintains a set pressure to ensure the CO₂ in the drying gas remains in its supercritical state before actuating the drying. After the drying, the drying gas is subsequently exhausted as the exhausted gas, and the contaminant of the exhausted gas is continuously monitored to determine the drying endpoint.

In certain embodiments, a substrate (e.g., a semiconductor substrate, not shown in FIG. 1) can be positioned within the pipe downstream of the heater 106 and upstream of the sensor 120, ensuring the substrate is applied to be dried by the drying gas including supercritical CO₂.

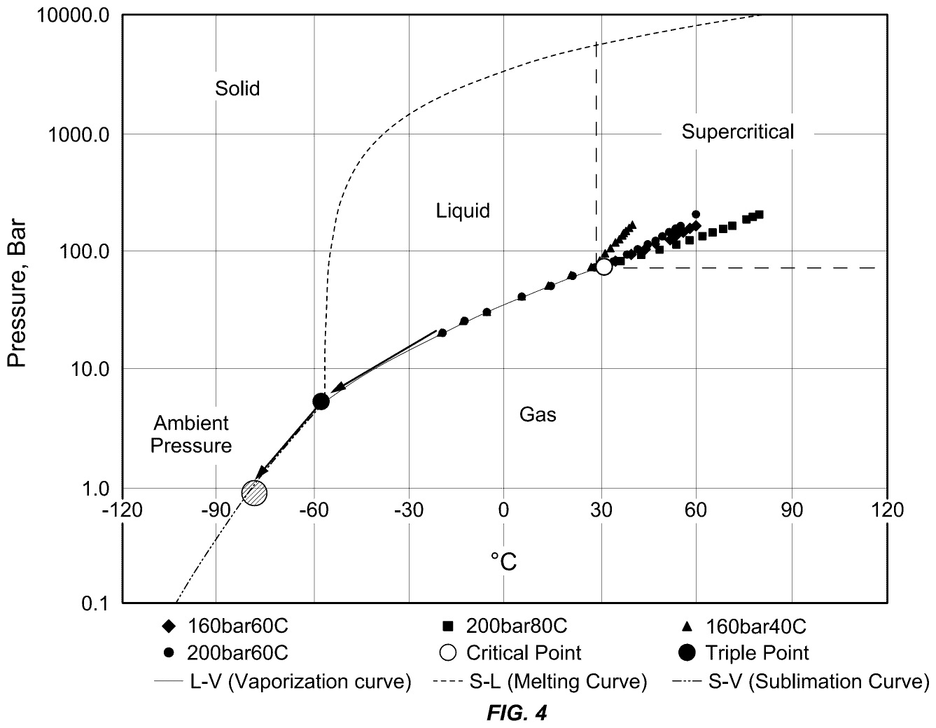

In accordance with the disclosed subject matter, the mixture of IPA and/or H2O (the second flow, as a solvent) and liquid CO₂ (the first flow) is delivered into the heater 106 to generate the drying gas including supercritical CO₂. The conditions in the heater 106 are maintained above the critical temperature and pressure for CO₂ to create the drying gas. For example, the conditions can be determined with specific parameters, e.g., temperature and pressure, according to a phase diagram, as referenced to FIG. 4.

IPA has a significant role in drying and monitoring. Rather than thermal moderating, IPA provides a drying solvent for supercritical CO₂, providing more than a threefold reduction in surface tension compared to water. Further reduction in surface tension can be achieved by heating IPA during the drying step. Despite these benefits, IPA-included drying techniques still carry a risk of residual solvent retention and incomplete collapse mitigation. Therefore, the monitoring for IPA in the exhaust gas can be continued after the drying.

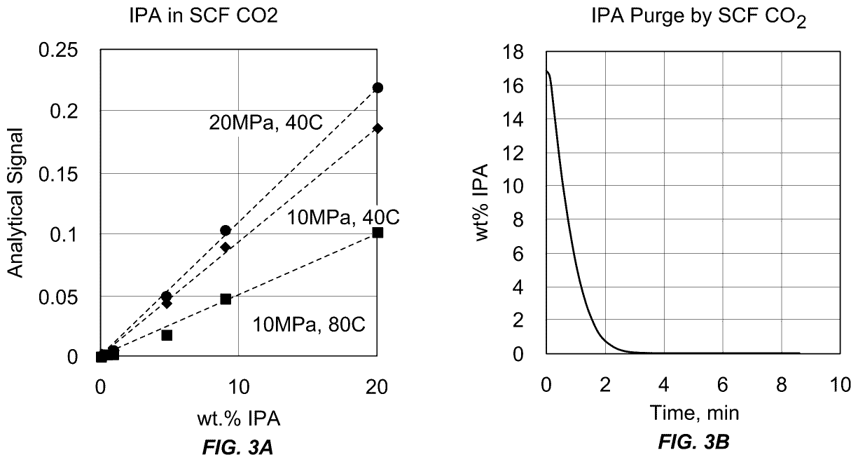

The IPA monitoring in the exhaust gas can be operated, e.g., via spectral analysis. Referring to FIG. 3A, IPA monitoring experimental data is shown. The calibration curves at various temperature and pressure illustrates the concentration of IPA co-dissolved in supercritical CO₂ as a detectable signal, e.g., certain physical properties (e.g., IR absorbance, density). The curve shows an accurate quantitative endpoint tracking for IPA content in the calibration mode regardless of the temperature and pressure, thereby demonstrating validity and reliability of the method and system in the disclosed subject matter. FIG. 3B presents the evolution of a monitored IPA concentration over time during a supercritical CO₂ drying process. It shows a declining curve that levels off stably once IPA is fully removed, which marks the drying endpoint. Thus, the monitoring realizes a real-time endpoint detection in supercritical drying based on observable IPA concentration that correlates with IPA removal. After the detecting, an exhausting treatment is followed.

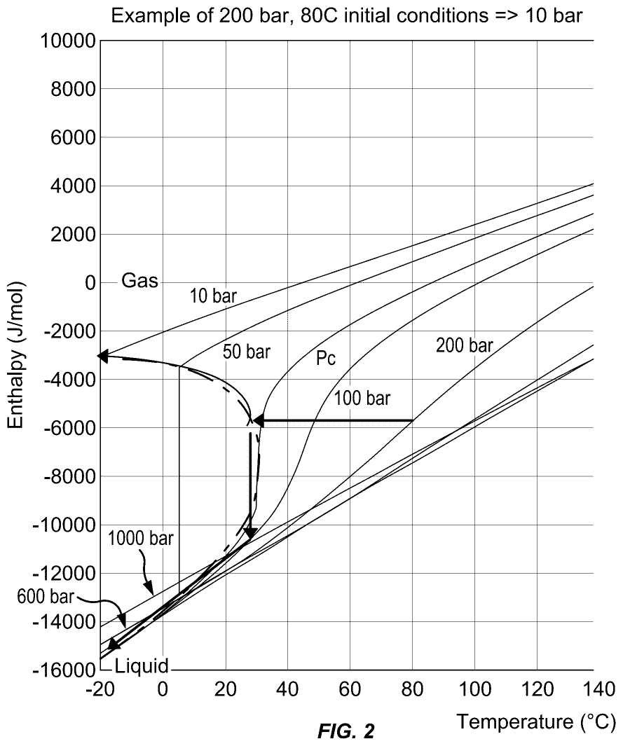

With reference to FIG. 2, the temperature of the mixture is increased in the heater 106 via heat exchanging, up to or above the supercritical temperature, e.g., about 32° C. Selectively, in the heater 106, the pressure can be maintained above the supercritical pressure, e.g., about 80 bar, 90 bar, or 100 bar. Such these conditions allow CO₂ of the mixture to transit to and maintain as supercritical CO₂, where CO₂ exhibits properties of both a liquid and a gas, securing for removing residues like IPA efficiently without surface tension when the drying gas is being delivered on the surface of the substrate. It is also noted that a rapid expansion of supercritical CO₂ during the monitoring results in a significant cooling, thereby degrading the efficiency and accuracy of monitoring. Therefore, as the exhaust gas transits through the pipe in the system, pressure change may occur during the delivery int the pipes, potentially leading to instability or even disrupting the supercritical conditions of CO₂.

To address this issue, following the sensor 120, the back-pressure valve 110 is employed to maintain pressure conditions for CO₂, e.g., via regulating the flow rate of the exhaust gas, thereby ensuring the stability of the flow state and facilitating subsequent drying and exhausting operations in the system. Further, with reference to FIG. 2 regarding CO₂ transitions with different graded pressures (10 to 200 bar), it has been demonstrated that with the decrease of pressure, the initial gas-liquid transition temperature of CO₂ decreases. Notably, during the exhausting, the exhausting gas undergoes a rapid Joule-Thompson expansion in the exhaust pipe 108, wherein the pressure of the exhaust gas drops. This expansion occurs when the high-pressure drying gas, typically around 200 bar at 80° C., is released through a pressure control valve into a lower pressure region. For example, from comparative high-pressure units, e.g., the back-pressure valve or drying chamber, the drying gas is delivered to low pressure units, e.g., the exhaust pipe with an open terminal end, which connects to the atmosphere. As the drying gas expands, the temperature drops significantly due to the reduction in pressure, e.g., to or below 10 bar at −20° C.

FIG. 4 depicts phase transitions between three phases and a supercritical phase for CO₂. In phase transitions of pure CO₂, the temperature can drop to below −70° C., e.g., −78.5° C. during the expansion. This is a direct result of a Joule-Thompson effect, where the cooling of the gas occurs without any external heat exchange, simply due to the pressure drop.

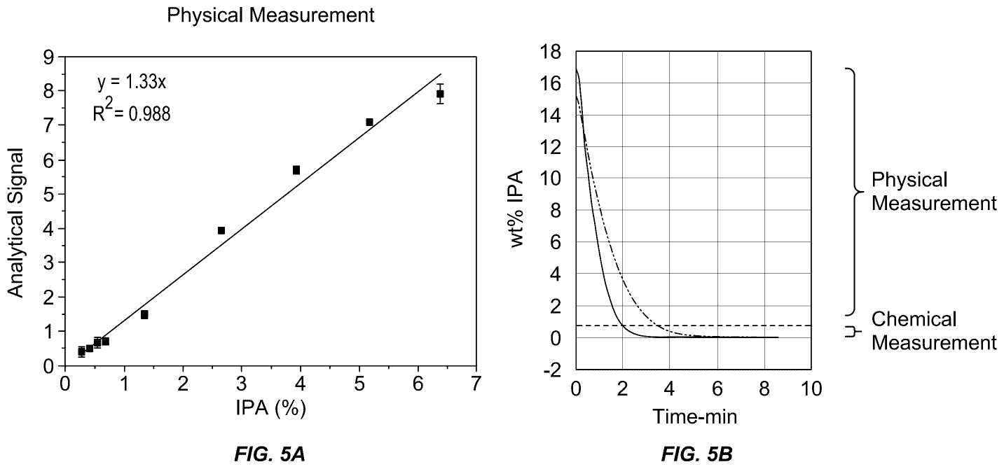

FIGS. 5A-5B illustrate the real-time monitoring of IPA concentration in the exhaust gas in a supercritical CO₂ drying process, demonstrating both the feasibility and effectiveness of physical measurements for endpoint detection. FIG. 5A shows a calibration curve plotting IPA concentration against the corresponding analytical signal obtained via the sensor. The linear regression equation, y=1.33x, with an R² value of 0.988, confirms a strong linear relationship between the measured signal and IPA concentration in the disclosed subject matter. This high correlation validates the reliability of the sensor for quantitative detection of IPA levels in the exhaust gas.

FIG. 5B compares physical and chemical measurements of IPA concentration over time during a typical supercritical CO₂ drying process. The vertical axis represents the weight percentage (wt %) of IPA, while the horizontal axis represents time in minutes. The purple curve shows the sensor's real-time response, rapidly detecting the IPA decrease during the drying phase. The orange curve reflects the delayed signal obtained from a chemical assay or analysis. The dashed horizontal line represents a threshold IPA concentration below which the endpoint is considered to have been reached—this threshold corresponds to the substantial absence of IPA. The physical measurement not only provides faster feedback but also enables continuous, in situ monitoring, allowing for precise and timely detection of the drying endpoint. Such figures demonstrate example validation of the disclosed subject matter in determining the endpoint based on a physical signal indicating the substantial absence of IPA.

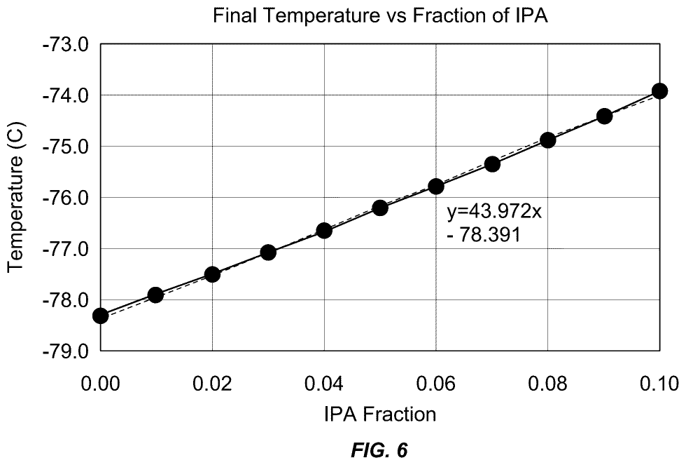

FIG. 6 illustrates the correlation between the fraction of isopropanol (IPA) in the exhaust gas and the final measured temperature the exhaust gas within the system, following a Joule-Thomson expansion. The vertical axis represents the temperature in degrees Celsius (° C.), while the horizontal axis indicates the IPA fraction (0-0.10).

A strong linear relationship is observed between the IPA fraction and the resulting temperature, with the regression line described by the equation:

$$y = 43.972 x - 78.391 \qquad ( 1 )$$

This relationship shows that even small changes in IPA content produce measurable shifts in the post-expansion temperature. As the IPA fraction decreases, the final temperature after expansion becomes more negative, approaching the baseline for pure CO₂. Thus, a low temperature control is readily enabled in the disclosed subject matter with safety and flexibility.

Thus, upon the calibration of the liner relationship shown in FIG. 6, the disclosed approach can apply to a detection of contaminants based on different thermodynamic properties of CO₂ and impurity (e.g., H₂O and/or IPA), e.g., tracking the decrease in temperature and observing when it stabilizes, allowing to determine the accurate endpoint of the drying process, preventing over-drying or under-drying of the materials. More than monitoring exhausted gas, there can be multiple specific approaches to ensure an accurate endpoint of drying, e.g., measuring heat energy required to get to specific temperature, temperature decrease during controlled versus Joule-Thompson expansion, or pressure corresponding to specific temperature; monitoring of any temperature-induced effect rather than temperature itself, e.g., but not limited to dew effect. The skilled person in the art will recognize and understand that such similar approaches are within the scope of the disclosed subject matter.

In certain embodiments, the disclosed subject matter further comprises monitoring IPA directly, for example, by determining the purity of the IPA used in the process. Impurities present in IPA may cause defects on the substrate during semiconductor processing. In advanced semiconductor manufacturing, even trace levels of such contaminants can serve as precursors to defect formation, particularly organic particles and moisture, adversely affecting device yield, reliability, and overall process performance. IPA purity can be monitored by a spectroscopic detection, gas chromatography, or electrical sensing.

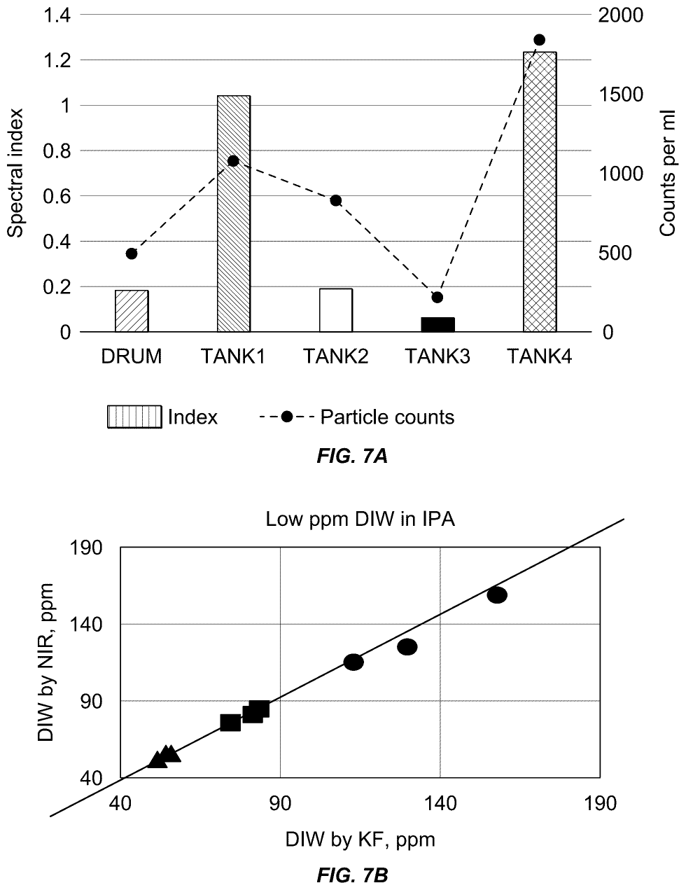

FIG. 7A shows a graph correlating the presence of organic contaminants, e.g., Acetone, in IPA with an increase in liquid particle count (LPC). As contaminant concentration rises, so does the number of particles, directly linking chemical purity to defectivity. This strengthens the justification for real-time IPA purity monitoring and provides validation for the importance of chemical quality control in wafer drying steps. FIG. 7B compares a non-reagent technique (e.g., optical or spectroscopic) for monitoring moisture content in IPA with a traditional Karl Fisher titration method. The graph demonstrates close agreement between the two, confirming the viability of non-destructive inline monitoring of water contamination in IPA at low ppm levels. Compared to traditional detection methods often rely on chemical reagents or time-delayed feedback loops, the disclosed subject matter demonstrates a real-time, reagent-free detection and identification for IPA purity.

In addition to the various embodiments depicted and claimed, the disclosed subject matter is also directed to other embodiments having other combinations of the features disclosed and claimed herein. As such, the features presented herein can be combined with each other in other manners within the scope of the disclosed subject matter such that the disclosed subject matter includes any suitable combination of the features disclosed herein. The foregoing description of specific embodiments of the disclosed subject matter has been presented for purposes of illustration and description. It is not intended to be exhaustive or to limit the disclosed subject matter to those embodiments disclosed.

What we claim is:

1. A system for monitoring supercritical CO₂ drying of a substrate, the system comprising:
a first pump configured to pump a first flow comprising liquid CO₂,
a second pump configured to pump a second flow comprising isopropyl alcohol (IPA),
a heater provided downstream of the first pump and second pump and configured to receive the first flow and the second flow, to generate a drying gas comprising supercritical CO₂ therefrom and to provide the drying gas to the substrate to induce drying thereof; and
a detector configured to detect an endpoint for the drying including a sensor positioned to continuously monitor an exhaust gas downstream of the drying and determine a concentration of IPA therein; wherein the endpoint is dependent on the determined IPA concentration.

2. The system of claim 1, wherein the detector further comprises a back-pressure valve downstream of the sensor.

3. The system of claim 1, wherein the exhaust pipe is position downstream of the back-pressure valve.

4. The system of claim 1, wherein the endpoint is determined upon a substantial absence of IPA.

5. The system of claim 1, wherein the detector further comprises an electronic module electrically connected with the sensor, and the electronic module is configured to determine continuing or terminating the drying.

6. A method for monitoring supercritical CO₂ drying of a substrate, the method comprising:
pumping a first flow comprising liquid CO₂ and a second flow comprising isopropyl alcohol (IPA),
generating a drying gas including supercritical CO₂ by mixing and heating the first flow and second flow,
drying the substrate using the drying gas, and
continuously monitoring an exhaust gas downstream of the drying, wherein the continuously monitoring comprises determining a concentration of IPA in the exhaust gas and an endpoint of the drying, wherein the endpoint is dependent on the determined IPA concentration.

7. The method of claim 6, wherein the heating temperature is from 40-100° C.

8. The method of claim 6, wherein the exhausted gas undergoes an expansion.

9. The method of claim 6, wherein the exhausted gas is expanded with a drop pressure from 200 bar to 1 bar.

10. The method of claim 6, further comprising releasing the exhaust gas from the detector.

11. The method of claim 6, further comprising regulating pressure of the drying gas downstream of the drying.

12. The method of claim 6, wherein the drying gas comprises IPA less than 10%.

13. The method of claim 6, wherein the endpoint is determined upon a substantial absence of IPA.

14. The method of claim 6, further comprising monitoring IPA purity for identifying defects of the substrate.

15. The method of claim 14, wherein the defects comprise particles and moisture.

16. The method of claim 14, wherein the IPA purity is monitored by a spectroscopic detection, gas chromatography, or electrical sensing.

17. The method of claim 6, wherein the second flow further comprises H₂O.
